(19) United States
(12) Patent Application Publication
(10) Pub. No.: US 2018/0143472 A1
(43) Pub. Date: May 24, 2018

(54) ARRAY SUBSTRATE AND DISPLAY PANEL

(71) Applicant: AU Optronics Corporation, HSIN-CHU (TW)

(72) Inventors: Yu-Jen CHEN, HSIN-CHU (TW); Pi-Chun YEH, HSIN-CHU (TW); Hsin-Chun HUANG, HSIN-CHU (TW); Ching-Sheng CHENG, HSIN-CHU (TW)

(21) Appl. No.: 15/814,502

(22) Filed: Nov. 16, 2017

(30) Foreign Application Priority Data
Nov. 21, 2016 (TW) 105138152

(51) Int. Cl. G02F 1/1368; H01L 27/12

(52) U.S. Cl. CPC G02F 1/1368; G09G 2320/0247; H01L 27/124

(57) ABSTRACT

A display panel includes a first sub-pixel, a second sub-pixel, and a third sub-pixel. The first sub-pixel has a relatively large feed-through voltage change and relatively small transmittance, and/or the first sub-pixel has relatively large line impedance and relatively small transmittance. By means of this design, a degree of image flicker is reduced.

### BACKGROUND

### Technical Field

The present invention relates to a display panel, and more particularly to a display panel which degree of image flicker is reduced.

### Related Art

A liquid crystal display apparatus is lightweight and thin, has low power consumption, and causes no radiation pollution. Because of the foregoing and other characteristics, liquid crystal display apparatuses have been widely applied on electronic products such as computer screens, mobile phones, personal digital assistants (PDAs), and flat-panel televisions. The liquid crystal display apparatus includes a thin film transistor substrate and an opposite substrate. A liquid crystal material layer is sandwiched between the two substrates. By changing a potential difference of the liquid crystal material layer, rotation angles of liquid crystal molecules inside the liquid crystal material layer can be changed, to cause light transmittance of the liquid crystal material layer to change to display different images.

Refer to FIG. 1. FIG. 1 is a schematic diagram of a thin film transistor liquid crystal display panel in the prior art. A display panel 10 includes a plurality of scan lines G1, . . . , Gm, a plurality of data lines S1, . . . , Sn, a plurality of storage capacitor lines C1, . . . , Cm, and a plurality of pixels. Each pixel includes a transistor 12, a storage capacitor 14, and a liquid crystal capacitor 16. A parasitic capacitance 18 exists between a gate and a drain of the transistor 12. A pixel that are connected to the scan line G1 and the data line S1 are used as an example. The gate of the transistor 12 is electrically connected to the scan line G1. A source of the transistor 12 is electrically connected to the data line S1. The drain of the transistor 12 is electrically connected to a pixel electrode (not represented). The storage capacitor 14 is formed between the drain of the transistor 12 and the storage capacitor line C1. The liquid crystal capacitor 16 is formed between the drain of the transistor 12 and a common voltage VCOM. A voltage applied on a first end of the liquid crystal capacitor 16 is referred to as a pixel voltage. The storage capacitor 14 is configured to store the pixel voltage until a next input of a data signal. A voltage applied on a second end of the liquid crystal capacitor 16 is a common voltage VCOM.

Refer to FIG. 2. FIG. 2 is a voltage waveform diagram of the display panel 10 in FIG. 1. A pixel connected to the scan line G1 and the data line S1 is used as an example. When a scan line voltage 22 of the scan line G1 rises from a voltage Vgl to a voltage Vgh, the transistor 12 is turned on. The pixel electrode is charged by a data line voltage 24 of the data line S1 within a duty time Ton of the scan line voltage 22. Therefore, a pixel voltage 26 of the pixel electrode substantially rises from a voltage Vdl to a voltage Vdh. After the duty time Ton of the scan line voltage 22, the scan line voltage 22 drops to the voltage Vgl. In this case, the transistor 12 is turned off. Therefore, the data line S1 cannot continue charging the pixel electrode. When the data line voltage 24 drops from the voltage Vdh to the voltage Vdl, the storage capacitor 14 keeps the pixel voltage at the voltage Vdh. Therefore, the pixel voltage 26 does not immediately drop to the voltage Vdl. However, when the scan line voltage 22 drops from the voltage Vgh to the voltage Vgl, because of a coupling effect of the parasitic capacitance 18, the pixel voltage 26 generates a pull-down feed-through voltage change ΔVp1. Similarly, when the duty time Ton of the scan line voltage 22 ends a next time, the pixel voltage 26 also generates a pull-down feed-through voltage change ΔVp2. The feed-through voltage change raises an unexpected drop of the pixel voltage 26, causing image flicker to occur in the thin film transistor liquid crystal display.

### SUMMARY

One of the objectives of the present invention is to provide a display panel having slight image flicker.

One of the objectives of the present invention is to set a pixel that has a relatively large feed-through voltage change to be a pixel that has relatively low transmittance, thereby reducing differences in an image flicker problem among display panels because of mass production.

One of the objectives of the present invention is to set a pixel that has a relatively large feed-through voltage change to be a pixel that has relatively low transmittance, thereby reducing a degree of image flicker.

One of the objectives of the present invention is to set a pixel that has a relatively large feed-through voltage change to be a pixel that has relatively low transmittance, thereby improving overall optical stability of a display panel.

One of the objectives of the present invention is to set a pixel relatively severely affected by line impedance to be a pixel that has relatively low transmittance, thereby reducing differences in a display effect among display panels due to mass production.

One of the objectives of the present invention is to set a pixel relatively severely affected by line impedance to be a pixel that has relatively low transmittance, thereby reducing unevenness perceived by human eyes in a display effect of a display panel.

One of the objectives of the present invention is to set a pixel relatively severely affected by line impedance to be a pixel that has relatively low transmittance, thereby improving overall optical stability of a display panel.

An embodiment of the present invention provides an array substrate, comprising a first sub-pixel having a first feed-through voltage change and first transmittance, wherein the first sub-pixel includes a first active element and a first pixel electrode electrically connected to the first active element; a second sub-pixel having a second feed-through voltage change and second transmittance, wherein the second sub-pixel includes a second active element and a second pixel electrode electrically connected to the second active element; and a third sub-pixel having a third feed-through voltage change and third transmittance wherein the third sub-pixel includes a third active element and a third pixel electrode electrically connected to and the third active element, and the first feed-through voltage change is greater than the second feed-through voltage change or the third feed-through voltage change, and the first transmittance is less than the second transmittance or the third transmittance; a first scan line, electrically connected to the first sub-pixel; a second scan line, electrically connected to the second sub-pixel; a third scan line, electrically connected to the third sub-pixel; and a first data line, electrically connected to the third sub-pixel, wherein the second active element is electrically connected between the third pixel electrode and the second pixel electrode, and the first active element is electrically connected between the second pixel electrode and the first pixel electrode.

An embodiment of the present invention provides an array substrate, comprising a first sub-pixel, a second sub-pixel, and a third sub-pixel that are located inside a first area, and comprising three basic sub-pixels located inside a second area, wherein the first sub-pixel, the second sub-pixel, and the third sub-pixel are substantially sequentially disposed in an arrangement direction, and the basic sub-pixels are substantially also sequentially disposed in the arrangement direction. A first distance between the first area and a edge of the array substrate is greater than a second distance between the second area and the edge of the array substrate. The first sub-pixel, the second sub-pixel, and the third sub-pixel have a different color arrangement from the basic sub-pixels, and the first sub-pixel is a blue sub-pixel, the second sub-pixel is a red sub-pixel, and the third sub-pixel is a green sub-pixel.

An embodiment of the present invention provides an array substrate, comprising: a first sub-pixel, having first transmittance, wherein the first sub-pixel includes a first active element and a first pixel electrode electrically connected to the first active element; a second sub-pixel, having second transmittance, wherein the second sub-pixel includes a second active element and a second pixel electrode electrically connected to the second active element; a third sub-pixel, having third transmittance, wherein the third sub-pixel includes a third active element and a third pixel electrode electrically connected to and the third active element; a first scan line, electrically connected to the first sub-pixel; a second scan line, electrically connected to the second sub-pixel; a third scan line, electrically connected to the third sub-pixel; and a first data line, electrically connected to the third sub-pixel, wherein the second active element is electrically connected between the third pixel electrode and the second pixel electrode, the first active element is electrically connected between the second pixel electrode and the first pixel electrode, and the first transmittance is less than the second transmittance or the third transmittance.

Both the foregoing general description about the present invention and the following detailed description about the embodiments are exemplary and are intended to explain the principles of the present invention, and provide further explanation of the claims of the present invention.

### BRIEF DESCRIPTION OF THE DRAWINGS

FIG. 1 is a schematic diagram of a thin film transistor liquid crystal display panel in the prior art;

FIG. 2 is a voltage waveform diagram of the display panel in FIG. 1;

FIG. 3A is a schematic diagram of a first embodiment of an array substrate according to the present invention;

FIG. 3B is a waveform schematic diagram of an operation of the array substrate in FIG. 3A;

FIG. 3C is a schematic top diagram of an array substrate according to a second embodiment of the present invention;

FIG. 3D is a schematic diagram of distribution of pixel groups located inside a first area in FIG. 3C;

FIG. 3E is a schematic diagram of distribution of pixel groups located inside a second area in FIG. 3C;

FIG. 4 is a schematic diagram of a third embodiment of an array substrate according to the present invention;

FIG. 5A is a schematic diagram of a fourth embodiment of an array substrate according to the present invention; and

FIG. 5B is a waveform schematic diagram of an operation of the array substrate in FIG. 5A.

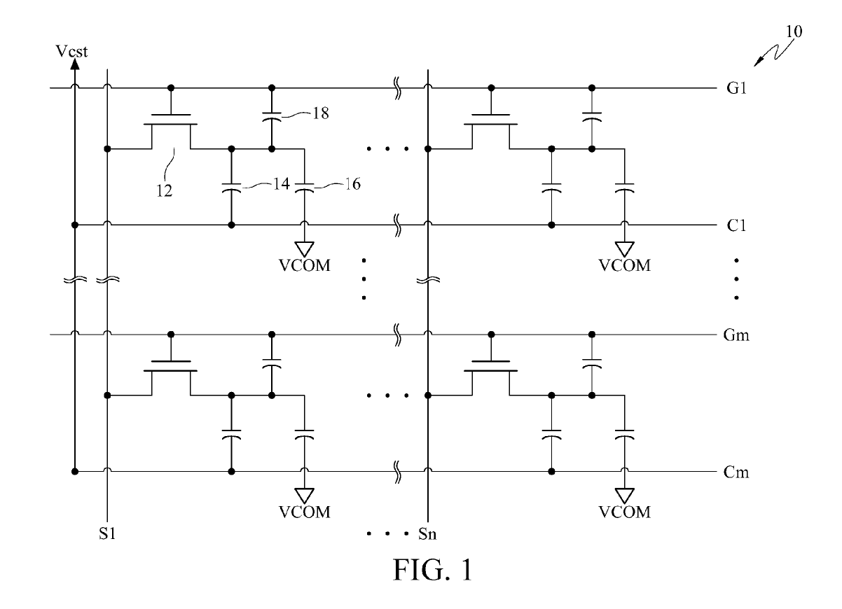

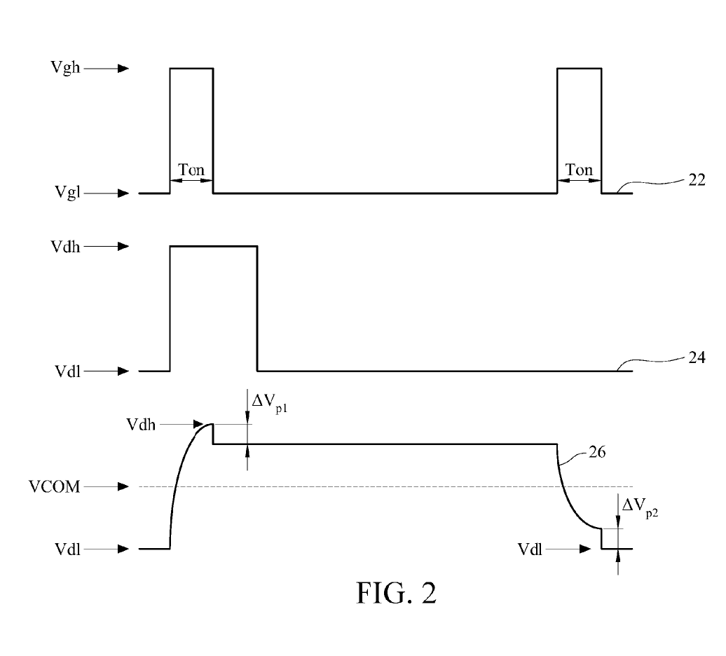

### DETAILED DESCRIPTION

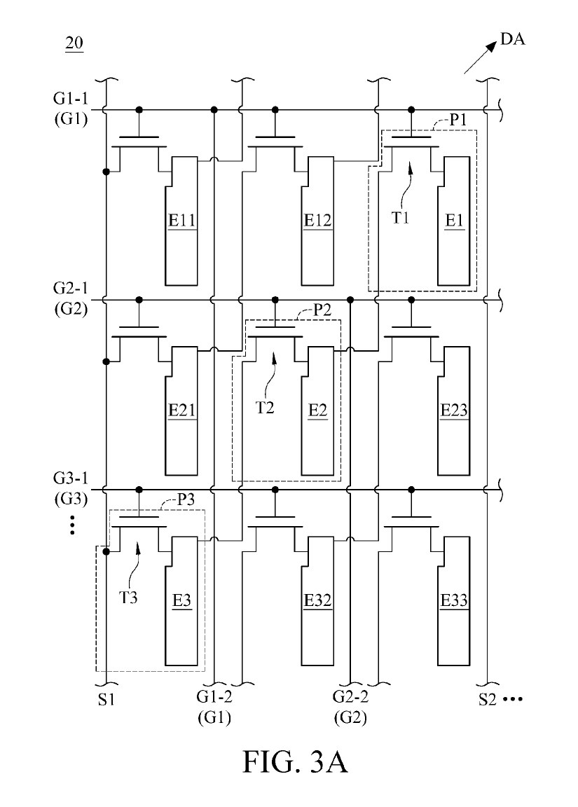

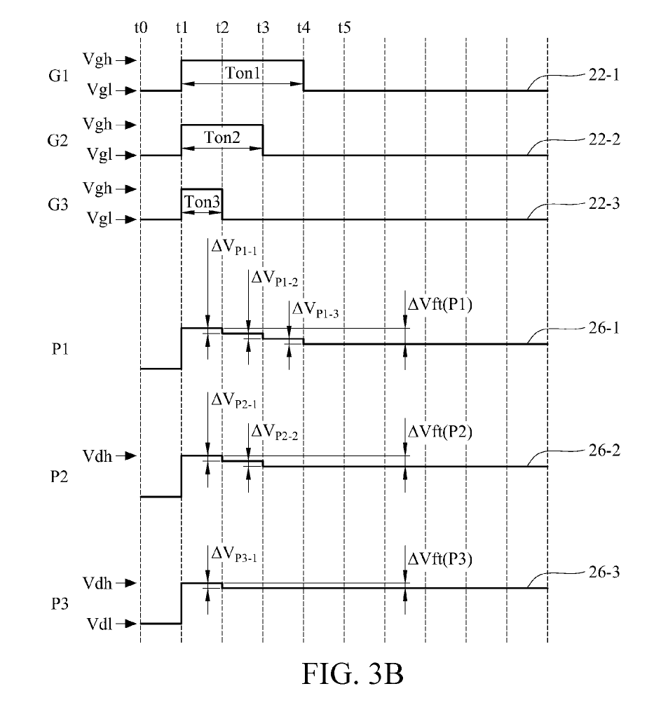

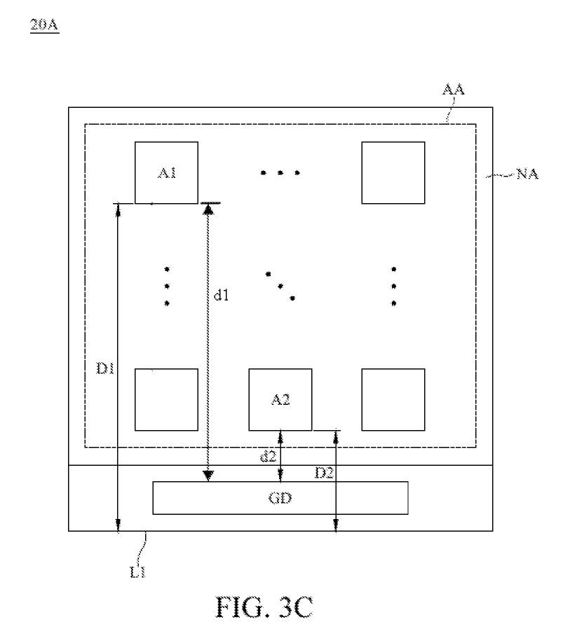

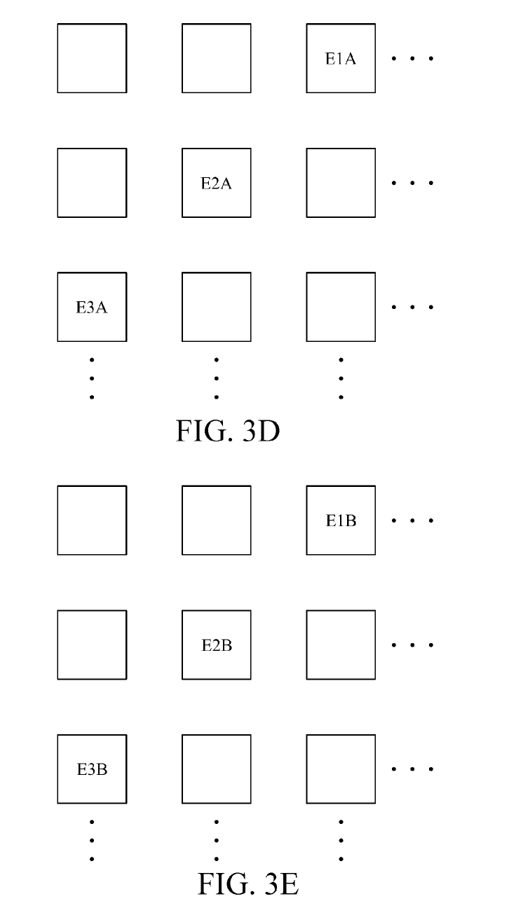

Refer to FIG. 3A to FIG. 3E. FIG. 3A is a schematic diagram of a first embodiment of an array substrate 20 according to the present invention. Referring to FIG. 3A, the array substrate 20 includes a plurality of sub-pixels P1, P2, P3, . . . . For ease of description, FIG. 3A shows only nine sub-pixels. Only three sub-pixels are provided with reference numerals, but this embodiment is not limited thereto.

The first sub-pixel P1 includes a first active element T1 and a first pixel electrode E1 electrically connected to the first active element T1. The second sub-pixel P2 includes a second active element T2 and a second pixel electrode E2 electrically connected to the second active element T2. The third sub-pixel P3 includes a third active element T3 and a third pixel electrode E3 electrically connected to the third active element T3. The first active element T1, the second active element T2, and the third active element T3 are, for example, thin film transistors.

The array substrate 20 further includes a first scan line G1 electrically connected to the first sub-pixel P1, a second scan line G2 electrically connected to the second sub-pixel P2, a third scan line G3 electrically connected to the third sub-pixel P3, and a first data line S1 electrically connected to the third sub-pixel P3. The first scan line G1 is electrically connected to an end of the first active element T1, the second scan line G2 is electrically connected to an end of the second active element T2, and the third scan line G3 is electrically connected to an end of the third active element T3. In this embodiment, for ease of description, only three scan lines are shown, but this embodiment is not limited thereto, and a quantity of scan lines of the array substrate 20 is greater than three.

When the array substrate in this embodiment is a component of a liquid crystal display panel, at least one sub-pixel further includes a liquid crystal capacitor and a storage capacitor. Refer to the prior art of this disclosure for effects of the liquid crystal capacitor and the storage capacitor and connection relationships thereof with other elements, which are not elaborated herein, and are not used to limit the present invention.

The array substrate 20 further includes the first data line S1 and a second data line S2. For ease of description, only two data lines are shown, but the present invention is not limited thereto. A quantity of data lines of the array substrate 20 is greater than two. The first data line S1 is electrically connected to the third sub-pixel P3, the first data line S1 is electrically connected to an end of the third active element T3, the second active element T2 is electrically connected between the third pixel electrode E3 and the second pixel electrode E2, and the first active element T1 is electrically connected between the second pixel electrode E2 and the first pixel electrode E1.

The first sub-pixel P1, the second sub-pixel P2, and the third sub-pixel P3 are substantially sequentially disposed in an arrangement direction DA. The arrangement direction DA is neither parallel nor perpendicular to an extending direction of the first scan line G1. For a signal transferred by using the first data line S1, display data of three columns (or three rows) of sub-pixels is transferred in an oblique direction. For example, the first data line S1 is configured to sequentially transfer the display data to the third sub-pixel P3, the second sub-pixel P2, and the first sub-pixel P1. For ease of description, in this embodiment, nine sub-pixels are drawn and used as an example. In addition to the first to third sub-pixels P1 to P3, there are six more sub-pixels which respectively have corresponding sub-pixel electrodes E11, E12, E21, E23, E32, and E33. Reference may be made to FIG. 3A for electrical connection relationships of the sub-pixel electrodes E11, E12, E21, E23, E32, and E33 with other sub-pixels and other elements. For example, the sub-pixel electrodes E21 and E12 are arranged in the arrangement direction DA and are, for example, electrically connected through at least one active element. The sub-pixel electrodes E32 and E23 are arranged in the arrangement direction DA and are, for example, electrically connected through at least one active element. The sub-pixel electrodes E11, E21, and E3 are, for example, in a same column and are electrically connected to the first data line S1 through corresponding active elements. The sub-pixel electrodes E11, E12, and E1 are, for example, in a same row and are electrically connected to the first scan line G1 through corresponding active elements. The sub-pixel electrodes E21, E2, and E23 are, for example, in a same row and are electrically connected to the second scan line G2 through corresponding active elements. The sub-pixel electrodes E3, E32, and E33 are, for example, in a same row and are electrically connected to the third scan line G3 through corresponding active elements.

Continue to refer to FIG. 3A. The array substrate 20 has a display area (not represented) and a peripheral area (not represented). For example, the peripheral area surrounds the display area and is not overlapped with the display area. Optionally (but the present invention is not limited thereto): The first scan line G1 has a first section G1-1 and a second section G1-2 that are located inside the display area, and the second section G1-2 is electrically connected between the first section G1-1 and a gate driving circuit that is located inside the peripheral area. The second scan line G2 has a first section G2-1 and a second section G2-2 that are located inside the display area, and the second section G2-2 is electrically connected between the first section G2-1 and the gate driving circuit. Similarly, the third scan line G3 has a first section G3-1 and a second section (not shown) that are located inside the display area. The rest scan lines have a similar design, which is not elaborated herein. The first sections G1-1, G2-1, G3-1, . . . , are, for example, arranged sequentially and in parallel. The second sections G1-2 and G2-2 are, for example, located between the data line S1 and the data line S2. Because the second sections G1-2, G2-2, . . . are mainly located inside the display area but are not located at the peripheral area, a quantity of leads that are disposed in the peripheral area can be reduced, thereby achieving an objective of a narrow bezel.

Refer to both FIG. 3A and FIG. 3B. FIG. 3B is a waveform schematic diagram of an operation of the array substrate 20 in FIG. 3A. Within a time interval from t1 to t2 (that is, a time interval between a moment t1 and a moment t2), when a third scan line voltage 22-3 of the third scan line G3 rises from a voltage Vgl to a voltage Vgh, the third active element T3 is turned on, and the third pixel electrode E3 is charged by a data line voltage (not drawn) of the first data line S1 within a duty time Ton3 of the third scan line voltage 22-3. Therefore, a third pixel voltage 26-3 of the third pixel electrode E3 substantially rises from a voltage Vdl to a voltage Vdh. After the duty time Ton3 of the third scan line voltage 22-3, that is, after the moment t2, the third scan line voltage 22-3 drops to the voltage Vgl. In this case, the third transistor T3 is turned off. Therefore, the first data line S1 cannot continue charging the third pixel electrode E3. When a voltage of the first data line drops from the voltage Vdh to the voltage Vdl, a storage capacitor of the third sub-pixel P3 keeps the third pixel voltage 26-3 at the voltage Vdh. Therefore, the third pixel voltage 26-3 does not immediately drop to the voltage Vdl. However, when the third scan line voltage 22-3 drops from the voltage Vgh to the voltage Vgl, because of a coupling effect of a parasitic capacitance of the third sub-pixel P3, the third pixel voltage 26-3 drops by a pull-down third feed-through voltage change ΔVft(P3). In this case, a phenomenon of image flicker occurs in the third sub-pixel P3. Refer to the prior art of the disclosure for the generation and description of parasitic capacitances, which are not elaborated herein, but are not used to limit the present invention.

Within a time interval from t1 to t3 (that is, a time interval between the moment t1 and a moment t3), when a second scan line voltage 22-2 of the second scan line G2 rises from the voltage Vgl to the voltage Vgh, the second active element T2 is turned on. The second active element T2 is electrically connected between the third pixel electrode E3 and the second pixel electrode E2. The second pixel electrode E2 is charged by the data line voltage of the first data line S1 through the third active element T3, the third pixel electrode E3, and the second active element T2 within a duty time Ton2 of the second scan line voltage 22-2. Therefore, within the time interval from t1 to t2, a second pixel voltage 26-2 of the second pixel electrode E2 substantially rises from the voltage Vdl to the voltage Vdh. However, after the moment t2, under the influence of the coupling effect of the parasitic capacitance of the third sub-pixel P3, that is, under the influence of a third feed-through voltage change ΔVft(P3), the second pixel voltage 26-2 drops by a pull-down feed-through voltage change ΔVp2-1. After the moment t3, when the second scan line voltage 22-2 drops from the voltage Vgh to the voltage Vgl, because of a coupling effect of a parasitic capacitance of the second sub-pixel P2, the second pixel voltage 26-2 further drops by a pull-down feed-through voltage change ΔVp2-2. Therefore, a second feed-through voltage change ΔVft (P2) of the second sub-pixel P2 is a sum of the feed-through voltage change ΔVp2-1 and the feed-through voltage change ΔVp2-2. The second feed-through voltage change ΔVft(P2) of the second sub-pixel P2 is approximately greater than the third feed-through voltage change ΔVft(P3).

Within a time interval from t1 to t4 (that is, a time interval between the moment t1 and a moment t4), when a first scan line voltage 22-1 of the first scan line G1 rises from the voltage Vgl to the voltage Vgh, the first active element T1 is turned on. The first active element T1 is electrically connected between the second pixel electrode E2 and the first pixel electrode E1. The first pixel electrode E1 is charged by the data line voltage of the first data line S1 through the third active element T3, the third pixel electrode E3, the second active element T2, the second pixel electrode E2, and the first active element T1 within a duty time Ton1 of the first scan line voltage 22-1. Therefore, within the time interval from t1 to t2, a first pixel voltage 26-1 of the first pixel electrode E1 substantially rises from the voltage Vdl to the voltage Vdh. However, after the moment t2, under the influence of the coupling effect of the parasitic capacitance of the third sub-pixel P3, that is, under the influence of the third feed-through voltage change ΔVft(P3), the first pixel voltage 26-1 drops by a pull-down feed-through voltage change ΔVp1-1. After the moment t3, under the influence of the coupling effect of the parasitic capacitance of the second sub-pixel P2, that is, under the influence of the second feed-through voltage change ΔVft (P2), the first pixel voltage 26-1 drops by a pull-down feed-through voltage change ΔVp1-2. After the moment t4, under the effect of a coupling effect of a parasitic capacitance affect of the first sub-pixel P1, the first pixel voltage 26-1 drops by a pull-down feed-through voltage change ΔVp1-3. Therefore, a first feed-through voltage change ΔVft (P1) of the first sub-pixel P1 is a sum of the feed-through voltage change ΔVp1-1, the feed-through voltage change ΔVp1-2, and the feed-through voltage change ΔVp1-3. The first feed-through voltage change ΔVft (P1) of the first sub-pixel P1 is approximately greater than the second feed-through voltage change ΔVft (P2) and/or the third feed-through voltage change ΔVft (P3). For relationships between the foregoing feed-through voltage changes and coupling capacitances, refer to Republic of China Patent No. 1415100, the content of which is incorporated by reference in the present invention but is not used to limit the present invention.

In this embodiment, the first sub-pixel P1 has the first feed-through voltage change ΔVft(P1) and first transmittance, the second sub-pixel P2 has the second feed-through voltage change ΔVft(P2) and second transmittance, the third sub-pixel P3 has the third feed-through voltage change ΔVft(P3) and third transmittance, the first feed-through voltage change ΔVft(P1) is approximately greater than the second feed-through voltage change ΔVft(P2) and/or the third feed-through voltage change ΔVft(P3), and the first transmittance is less than the second transmittance and/or the third transmittance. By means of this design, the original first sub-pixel P1 that has a relatively severe phenomenon of image flicker is designed to be a sub-pixel that has relatively low transmittance, so that the phenomenon of image flicker of the first sub-pixel P1 can be mitigated. Therefore, human eyes perceive the phenomenon of image flicker of the first sub-pixel P1 relatively slightly. Optionally, by means of a similar concept, the original second sub-pixel P2 that has a less severe phenomenon of image flickering is designed to be a sub-pixel that has lower transmittance, and the original third sub-pixel P3 that has a relatively mild phenomenon of image flickering is designed to be a sub-pixel that has the highest transmittance. The first sub-pixel P1 is, for example, a blue sub-pixel, the second sub-pixel P2 is, for example, a red sub-pixel, and the third sub-pixel P3 is, for example, a green sub-pixel. Therefore, when being viewed by human eyes, for a display panel including this array substrate, a degree of image flicker is reduced. In this embodiment, a pixel that has a relatively large feed-through voltage change is set to be a pixel that has relatively low transmittance, thereby reducing differences in an image flicker problem among display panels because of mass production and/or thereby improving overall optical stability of a display panel.

Refer to FIG. 3C. FIG. 3C is a schematic top diagram of the array substrate 20A according to a second embodiment of the present invention. Referring to FIG. 3C, the array substrate 20A has a display area AA and a peripheral area NA. A gate driving circuit GD is located inside the peripheral area NA. For example, the peripheral area NA surrounds the display area AA and is not overlapped with the display area AA. The display area AA has a first area A1 and a second area A2. A distance D1 between the first area A1 and a edge L1 of the array substrate 20A is greater than a distance D2 between the second area A2 and the edge L1 of the array substrate 20A. A distance d1 between the first area A1 and a driving circuit is greater than a distance d2 between the second area A2 and the driving circuit. The driving circuit is adjacent to the edge L1 and is electrically connected to the sub-pixels. The driving circuit is, for example, the gate driving circuit GD. The gate driving circuit GD is substantially located between the edge L1 and the first area A1. The gate driving circuit GD is substantially located between the edge L1 and the second area A2.

Refer to all FIG. 3C to FIG. 3E. FIG. 3D is a schematic diagram of distribution of pixel groups located inside the first area A1. FIG. 3E is a schematic diagram of distribution of pixel groups located inside the second area A2. Refer to both FIG. 3A and FIG. 3D, for ease of description, FIG. 3D shows, but is not limited to, nine sub-pixels. A first sub-pixel E1A, a second sub-pixel E2A, and a third sub-pixel E3A are located inside the first area A1. The first sub-pixel E1A, the second sub-pixel E2A, and the third sub-pixel E3A are respectively similar to the first sub-pixel P1, the second sub-pixel P2, and the third sub-pixel P3 in FIG. 3A. The first sub-pixel E1A, the second sub-pixel E2A, and the third sub-pixel E3A are substantially sequentially disposed in an arrangement direction DA. The connection relationships between the first sub-pixel E1A, the second sub-pixel E2A, and the third sub-pixel E3A and corresponding scan lines, data lines, and other elements, and sub-pixel attributes of the first sub-pixel E1A, the second sub-pixel E2A, and the third sub-pixel E3A refer to those in FIG. 3A. The rest sub-pixels in FIG. 3D that are not provided with reference numerals also refer to those in FIG. 3A. The rest sub-pixels are not elaborated herein, and are not used to limit the present invention.

Refer to both FIG. 3D and FIG. 3E. For ease of description, FIG. 3E shows, but is not limited to, nine sub-pixels. Basic sub-pixels E1B, E2B, and E3B are located inside the second area A2. The basic sub-pixels E1B, E2B, and E3B are substantially sequentially disposed in the arrangement direction DA. Refer to FIG. 3A for the connection relationships between the basic sub-pixels E1B, E2B, and E3B and corresponding scan lines, data lines, the rest sub-pixels, other elements and the connection relationships between the basic sub-pixels E1B, E2B, and E3B, which are not elaborated herein, and are not used to limit the present invention.

It should be specifically noted that a manner of color arrangement of the first sub-pixel E1A, the second sub-pixel E2A, and the third sub-pixel E3A is different from a manner of color arrangement of the basic sub-pixels E1B, E2B, and E3B. For example, when the first sub-pixel E1A, the second sub-pixel E2A, and the third sub-pixel E3A are respectively a blue sub-pixel, a red sub-pixel, and a green sub-pixel, the basic sub-pixel E1B, the basic sub-pixel E2B, and the basic sub-pixel E3B are sequentially not in an arrangement manner of a blue sub-pixel, a red sub-pixel, and a green sub-pixel, but instead, are in another manner of color arrangement. The basic sub-pixel E1B, the basic sub-pixel E2B, and the basic sub-pixel E3B are, for example, a blue sub-pixel, a green sub-pixel, and a red sub-pixel, respectively.

Refer to FIG. 3C again. Compared with the second area A2, sub-pixel groups inside the first area A1 are relatively far away from a gate driving circuit GD. Therefore, the sub-pixel groups inside the first area A1 are under relatively great influence of line impedance, in addition to the influence of a feed-through voltage change. A display effect inside the first area A1 is relatively undesirable. By means of the inventive concept in this embodiment, the design of the sub-pixel groups inside the first area A1 is adjusted but the design of the sub-pixel groups inside the second area A2 is not adjusted. The original first sub-pixel E1A that has a relatively severe phenomenon of image flicker is designed to be a sub-pixel that has relatively low transmittance, so that a phenomenon of image flicker of the first sub-pixel E1A can be mitigated. Therefore, human eyes perceive the phenomenon of image flicker of the first sub-pixel E1A relatively slightly. Optionally, by means of a similar concept, the original second sub-pixel E2A that has a less severe phenomenon of image flicker is designed to be a sub-pixel that has lower transmittance, and the original third sub-pixel E3A that has a relatively mild phenomenon of image flicker is designed to be a sub-pixel that has the highest transmittance. The first sub-pixel E1A is, for example, a blue sub-pixel, the second sub-pixel E2A is, for example, a red sub-pixel, and the third sub-pixel E3A is, for example, a green sub-pixel. Therefore, when being viewed (for example, by human eyes), for a display panel including this array substrate, a degree of image flicker is reduced. In this embodiment, a pixel that has a relatively large feed-through voltage change is set to be a pixel that has relatively low transmittance, thereby reducing differences in an image flicker problem among display panels because of mass production and/or thereby improving overall optical stability of a display panel.

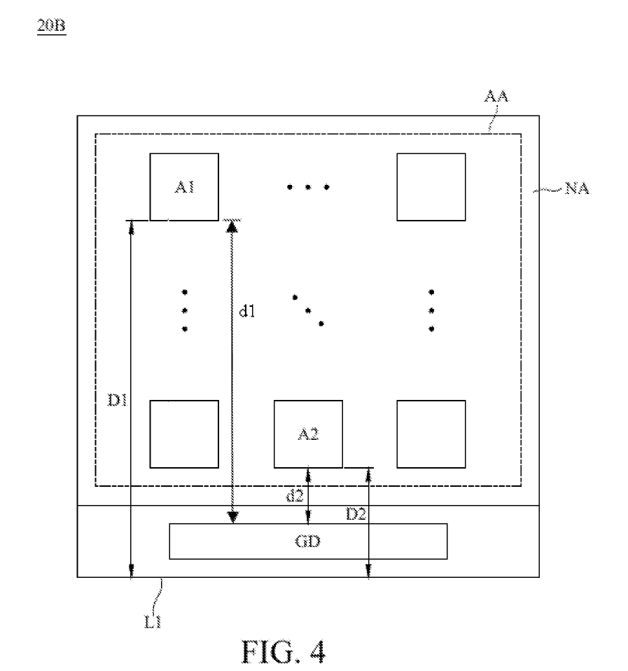

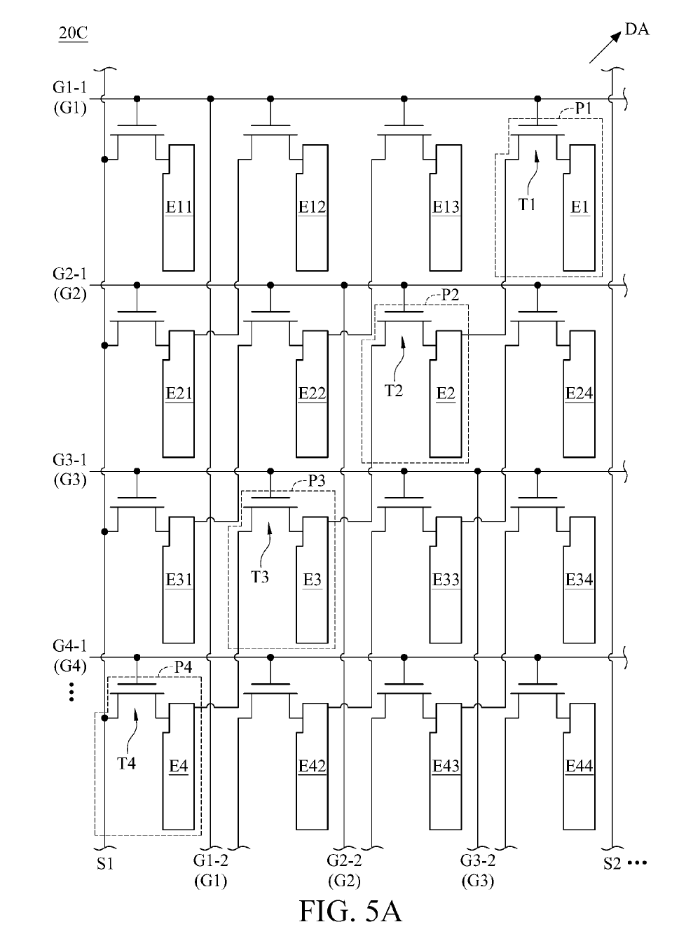

FIG. 4 is a schematic diagram of a third embodiment of the array substrate 20B according to the present invention. Referring to FIG. 4, the array substrate 20B has a display area AA and a peripheral area NA. The gate driving circuit GD is located inside the peripheral area NA. For example, the peripheral area NA surrounds the display area AA and is not overlapped with the display area AA. The display area AA has the first area A1 and the second area A2. A distance D1 between the first area A1 and a edge L1 of the array substrate 20B is greater than a distance D2 between the second area A2 and the edge L1 of the array substrate 20B. A distance d1 between the first area A1 and a driving circuit is greater than a distance d2 between the second area A2 and the driving circuit. The driving circuit is adjacent to the edge L1 and is electrically connected to the sub-pixels. The driving circuit is, for example, the gate driving circuit GD. The gate driving circuit GD is substantially located between the edge L1 and the first area A1. The gate driving circuit GD is substantially located between the edge L1 and the second area A2. Compared with the second area A2, the sub-pixel groups inside the first area A1 are relatively far away from the gate driving circuit GD. Therefore, the sub-pixel groups inside the first area A1 are under relatively great influence of line impedance, in addition to the influence of a feed-through voltage change. A display effect inside the first area A1 is relatively undesirable. Therefore, an original sub-pixel in the first area A1 that has a relatively severe phenomenon of image flicker is designed to be a sub-pixel that has relatively low transmittance, and an original sub-pixel in the second area A2 that has a phenomenon of image flicker less than that of sub-pixel in the first area A1 is designed to be a sub-pixel that has relatively high transmittance. Therefore, human eyes perceive the phenomenon of image flicker of the first area A1 relatively slightly. The sub-pixel inside the first area A1 is, for example, a blue sub-pixel, and the sub-pixel inside the second area A2 is, for example, a red sub-pixel or a green sub-pixel. Therefore, when being viewed (for example, being viewed by human eyes), for a display panel including this array substrate, a degree of image flicker is reduced. Therefore, in this embodiment, a pixel that has a relatively large feed-through voltage change is set to be a pixel that has relatively low transmittance, thereby reducing differences in an image flicker problem among display panels because of mass production and/or thereby improving overall optical stability of a display panel. In this embodiment, a quantity of sub-pixels in the first area A1 and a quantity of sub-pixels in the second area A2 are, for example, the same or different. Connection relationships between sub-pixels and other elements in the first area A1 and connection relationships between sub-pixels and other elements in the second area A2 may also be the same or different, and are not used to limit the present invention.

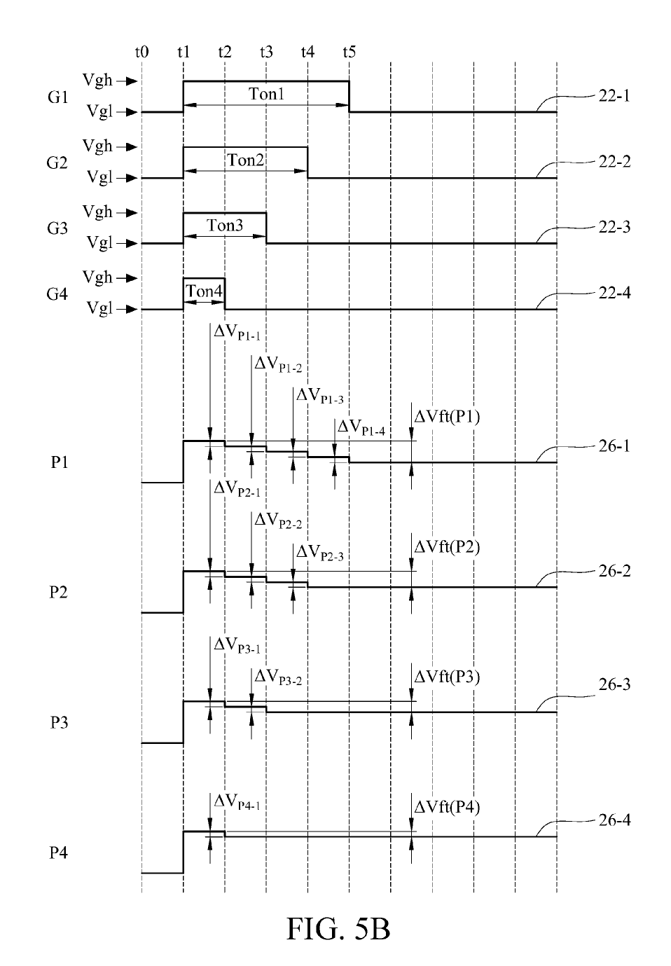

FIG. 5A is a schematic diagram of a fourth embodiment of an array substrate 20C according to the present invention. FIG. 5B is a waveform schematic diagram of an operation of the array substrate 20C in FIG. 5A. Referring to FIG. 5A, the array substrate 20C includes a plurality of sub-pixels P1, P2, P3, P4, . . . . For ease of description, FIG. 5A shows only sixteen sub-pixels. Only four sub-pixels are provided with reference numerals, but this embodiment is not limited thereto.

The first sub-pixel P1 includes a first active element T1 and a first pixel electrode E1 electrically connected to the first active element T1. The second sub-pixel P2 includes a second active element T2 and a second pixel electrode E2 electrically connected to the second active element T2. The third sub-pixel P3 includes a third active element T3 and a third pixel electrode E3 electrically connected to the third active element T3. The fourth sub-pixel P4 includes a fourth active element T4 and a fourth pixel electrode E4 electrically connected to the fourth active element T4. The first active element T1, the second active element T2, the third active element T3, and the fourth active element T4 are, for example, thin film transistors.

The array substrate 20C further includes a first scan line G1 electrically connected to the first sub-pixel P1, a second scan line G2 electrically connected to the second sub-pixel P2, a third scan line G3 electrically connected to the third sub-pixel P3, and a fourth scan line G4 electrically connected to the fourth sub-pixel P4, and a first data line S1 electrically connected to the fourth sub-pixel P4. The first scan line G1 is electrically connected to an end of the first active element T1. The second scan line G2 is electrically connected to an end of the second active element T2. The third scan line G3 is electrically connected to an end of the third active element T3. The fourth scan line G4 is electrically connected to an end of the fourth active element T4. In this embodiment, for ease of description, only four scan lines are shown, but the present invention is not limited thereto. A quantity of scan lines of the array substrate 20C is greater than four.

When the array substrate in this embodiment is a component of a liquid crystal display panel, at least one sub-pixel further includes a liquid crystal capacitor and a storage capacitor. Refer to the prior art of this disclosure for effects of the liquid crystal capacitor and the storage capacitor and connection relationships thereof with other elements, which are not elaborated herein, and are not used to limit the present invention.

The array substrate 20C further includes the first data line S1 and a second data line S2. For ease of description, only two data lines are shown, but the present invention is not limited thereto. A quantity of data lines of the array substrate 20C is greater than two. The first data line S1 is electrically connected to the fourth sub-pixel P4. The first data line S1 is electrically connected to an end of the fourth active element T4. The third active element T3 is electrically connected between the fourth pixel electrode E4 and the third pixel electrode E3. The second active element T2 is electrically connected between the third pixel electrode E3 and the second pixel electrode E2. The first active element T1 is electrically connected between the second pixel electrode E2 and the first pixel electrode E1.

The first sub-pixel P1, the second sub-pixel P2, the third sub-pixel P3, and the fourth sub-pixel P4 are substantially sequentially disposed in an arrangement direction DA. The arrangement direction DA is neither parallel nor perpendicular to an extending direction of the first scan line G1. For a signal transferred by using the first data line S1, display data of four columns (or four rows) of sub-pixels is transferred in an oblique direction. For example, the first data line S1 is configured to sequentially transfer the display data to the fourth sub-pixel P4, the third sub-pixel P3, the second sub-pixel P2, and the first sub-pixel P1. For ease of description, in this embodiment, sixteen sub-pixels are shown as an example. In addition to the first to fourth sub-pixels P1 to P4, there are twelve more sub-pixels that respectively have corresponding sub-pixel electrodes E11, E12, E13, E21, E22, E24, E31, E33, E34, E42, E43, and E44. For electrical connection relationships between the sub-pixel electrodes E11, E12, E13, E21, E22, E24, E31, E33, E34, E42, E43, and E44 and other sub-pixels and other elements, reference may be made to FIG. 5A. For example, the sub-pixel electrodes E21 and E12 are arranged in the arrangement direction DA and are, for example, electrically connected through at least one active element. The sub-pixel electrodes E43 and E34 are arranged in the arrangement direction DA and are, for example, electrically connected through at least one active element. The sub-pixel electrodes E11, E21, E31, and E4 are, for example, in a same column and are electrically connected to the first data line S1 through corresponding active elements. The sub-pixel electrodes E11, E12, E13, and E1 are, for example, in a same row and are electrically connected to the first scan line G1 through corresponding active elements. The sub-pixel electrodes E21, E22, E2, and E24 are, for example, in a same row and are electrically connected to the second scan line G2 through corresponding active elements. The sub-pixel electrodes E31, E3, E33, and E34 are, for example, in a same row and are electrically connected to the third scan line G3 through corresponding active elements. The sub-pixel electrodes E4, E42, E43, and E44 are, for example, in a same row and are electrically connected to the fourth scan line G4 through corresponding active elements.

Continue to refer to FIG. 5A. The array substrate 20C has a display area (not represented) and a peripheral area (not represented). For example, the peripheral area surrounds the display area and is not overlapped with the display area AA. Optionally (but the present invention is not limited thereto): The first scan line G1 has a first section G1-1 and a second section G1-2 that are located inside the display area. The second section G1-2 is electrically connected between the first section G1-1 and a gate driving circuit that is located at the peripheral area. The second scan line G2 has a first section G2-1 and a second section G2-2 that are located inside the display area. The second section G2-2 is electrically connected between the first section G2-1 and the gate driving circuit. The third scan line G3 has a first section G3-1 and a second section G3-2 that are located inside the display area. The second section G3-2 is electrically connected between the first section G3-1 and the gate driving circuit. Similarly, the fourth scan line G4 has a first section G4-1 and a second section (not shown) that are located inside the display area. The rest scan lines have a similar design, and are not elaborated herein. The first sections G1-1, G2-1, G3-1, G4-1, . . . are, for example, arranged sequentially and in parallel. The second sections G1-2, G2-2, and G3-2 are, for example, located between the data line S1 and the data line S2. Because the second sections G1-2, G2-2, G3-2, . . . are mainly located inside the display area but are not located at the peripheral area, a quantity of leads that are disposed in the peripheral area can be reduced, thereby achieving an objective of a narrow bezel.

Refer to both FIG. 5A and FIG. 5B. FIG. 5B is a waveform schematic diagram of an operation of the array substrate 20C in FIG. 5A. Refer to both FIG. 3B and FIG. 5B. For ease of description, similar reference numerals are omitted in FIG. 5B. With reference to FIG. 3B and description corresponding to FIG. 3B, a person skilled in the art may understand similar technical content in FIG. 5B. Within a time interval from t1 to t2 (that is, a time interval between a moment t1 and a moment t2), when a fourth the scan line voltage 22-4 of the fourth scan line G4 rises from a voltage Vgl to a voltage Vgh, the fourth active element T4 is turned on. The fourth pixel electrode E4 is charged by a data line voltage (not drawn) of the first data line S1 within a duty time Ton4 of the fourth the scan line voltage 22-4. Therefore, a fourth pixel voltage 26-4 of the fourth pixel electrode E4 substantially rises from a voltage Vdl to a voltage Vdh. After the duty time Ton 4 of the fourth the scan line voltage 22-4, that is, after the moment t2, the fourth the scan line voltage 22-4 drops to the voltage Vgl. In this case, the fourth transistor T4 is turned off. Therefore, the first data line S1 cannot continue charging the fourth pixel electrode E4. When a voltage of the first data line drops from the voltage Vdh to the voltage Vdl, a storage capacitor of the fourth sub-pixel P4 keeps the fourth pixel voltage 26-4 at the voltage Vdh. Therefore, the fourth pixel voltage 26-4 does not immediately drop to the voltage Vdl. However, when the fourth the scan line voltage 22-4 drops from the voltage Vgh to the voltage Vgl, because of a coupling effect of a parasitic capacitance of the fourth sub-pixel P4, the fourth pixel voltage 26-4 drops by a pull-down fourth feed-through voltage change ΔVft(P4). In this case, a phenomenon of image flicker occurs in the fourth sub-pixel P4. Refer to the prior art of the disclosure for the generation and description of parasitic capacitances, which are not elaborated herein, but are not used to limit the present invention.

Within a time interval from t1 to t3 (that is, a time interval between the moment t1 and a moment t3), when the third scan line voltage 22-3 of the third scan line G3 rises from the voltage Vgl to the voltage Vgh, the third active element T3 is turned on. The third active element T3 is electrically connected between the fourth pixel electrode E4 and the third pixel electrode E3. The third pixel electrode E3 is charged by the data line voltage of the first data line S1 through the fourth active element T4, the fourth pixel electrode E4, and the third active element T3 within a duty time Ton3 of the third scan line voltage 22-3. Therefore, within the time interval from t1 to t2, the third pixel voltage 26-3 of the third pixel electrode E3 substantially rises from the voltage Vdl to the voltage Vdh. However, after the moment t2, under the influence of the coupling effect of the parasitic capacitance of the fourth sub-pixel P4, that is, under the effect of the fourth feed-through voltage change ΔVft(P4), the third pixel voltage 26-3 drops by a pull-down feed-through voltage change ΔVp3-1. After the moment t3, when the third scan line voltage 22-3 drops from the voltage Vgh to the voltage Vgl, because of a coupling effect of a parasitic capacitance of the third sub-pixel P3, the third pixel voltage 26-3 drops by a pull-down feed-through voltage change ΔVp3-2. Therefore, a third feed-through voltage change ΔVft(P3) of the third sub-pixel P3 is a sum of the feed-through voltage change ΔVp3-1 and the feed-through voltage change ΔVp3-2. The third feed-through voltage change ΔVft(P3) of the third sub-pixel P3 is approximately greater than the fourth feed-through voltage change ΔVft(P4).

Within a time interval from t1 to t4 (that is, a time interval between the moment t1 and a moment t4), when the second scan line voltage 22-2 of the second scan line G2 rises from the voltage Vgl to the voltage Vgh, the second active element T2 is turned on. The second active element T2 is electrically connected between the third pixel electrode E3 and the second pixel electrode E2. The second pixel electrode E2 is charged by the data line voltage of the first data line S1 through the fourth active element T4, the fourth pixel electrode E4, the third active element T3, the third pixel electrode E3, and the second active element T2 within a duty time Ton2 of the second scan line voltage 22-2. Therefore, within the time interval from t1 to t2, a second pixel voltage 26-2 of the second pixel electrode E2 substantially rises from the voltage Vdl to the voltage Vdh. However, after the moment t2, under the influence of the coupling effect of the parasitic capacitance of the fourth sub-pixel P4, that is, under the effect of the fourth feed-through voltage change ΔVft(P4), the second pixel voltage 26-2 drops by a pull-down feed-through voltage change ΔVp2-1. After the moment t3, under the influence of the coupling effect of the parasitic capacitance of the third sub-pixel P3, that is, under the influence of the third feed-through voltage change ΔVft(P3), the second pixel voltage 26-2 drops by a pull-down feed-through voltage change ΔVp2-2. After the moment t4, under the influence of a coupling effect of a parasitic capacitance of the second sub-pixel P2, the second pixel voltage 26-2 drops by a pull-down feed-through voltage change ΔVp2-3. Therefore, a second feed-through voltage change ΔVft(P2) of the second sub-pixel P2 is a sum of the feed-through voltage change ΔVp2-1, the feed-through voltage change ΔVp2-2, and the feed-through voltage change ΔVp2-3. The second feed-through voltage change ΔVft(P2) of the second sub-pixel P2 is approximately greater than the third feed-through voltage change ΔVft(P3) and/or the fourth feed-through voltage change ΔVft(P4).

Within a time interval from t1 to t5 (that is, a time interval between the moment t1 and a moment t5), when the first scan line voltage 22-1 of the first scan line G1 rises from the voltage Vgl to the voltage Vgh, the first active element T1 is turned on. The first active element T1 is electrically connected between the second pixel electrode E2 and the first pixel electrode E1. The first pixel electrode E1 is charged by the data line voltage of the first data line S1 through the fourth active element T4, the fourth pixel electrode E4, the third active element T3, the third pixel electrode E3, the second active element T2, the second pixel electrode E2, and the first active element T1 within a duty time Ton1 of the first scan line voltage 22-1. Therefore, within the time interval from t1 to t2, the first pixel voltage 26-1 of the first pixel electrode E1 substantially rises from the voltage Vdl to the voltage Vdh. However, after the moment t2, under the influence of the coupling effect of the parasitic capacitance of the fourth sub-pixel P4, that is, under the effect of the fourth feed-through voltage change ΔVft(P4), the first pixel voltage 26-1 drops by a pull-down feed-through voltage change ΔVp1-1. After the moment t3, under the influence of the coupling effect of the parasitic capacitance of the third sub-pixel P3, that is, under the influence of the third feed-through voltage change ΔVft(P3), the first pixel voltage 26-1 drops by a pull-down feed-through voltage change ΔVp1-2. After the moment t4, under the influence of the coupling effect of the parasitic capacitance of the second sub-pixel P2, the first pixel voltage 26-1 drops by a pull-down feed-through voltage change ΔVp1-3. After the moment t5, under the effect of a coupling effect of a parasitic capacitance affect of the first sub-pixel P1, the first pixel voltage 26-1 drops by a pull-down feed-through voltage change ΔVp1-4. Therefore, a first feed-through voltage change ΔVft(P1) of the first sub-pixel P1 is a sum of the feed-through voltage change ΔVp1-1, the feed-through voltage change ΔVp1-2, the feed-through voltage change ΔVp1-3, and the feed-through voltage change ΔVp1-4. The first feed-through voltage change ΔVft(P1) of the first sub-pixel P1 is approximately greater than the second feed-through voltage change ΔVft(P2) and/or the third feed-through voltage change ΔVft(P3) and/or the fourth feed-through voltage change ΔVft(P4). For relationships between the foregoing feed-through voltage changes and coupling capacitances, refer to Republic of China Patent No. 1415100, the content of which is incorporated by reference in the present invention but is not used to limit the present invention.

In this embodiment, the first sub-pixel P1 has the first feed-through voltage change ΔVft(P1) and first transmittance. The second sub-pixel P2 has the second feed-through voltage change ΔVft(P2) and second transmittance. The third sub-pixel P3 has the third feed-through voltage change ΔVft(P3) and third transmittance. The fourth sub-pixel P4 has the fourth feed-through voltage change ΔVft(P4) and fourth transmittance. The first feed-through voltage change ΔVft(P1) is approximately greater than the second feed-through voltage change ΔVft(P2) and/or the third feed-through voltage change ΔVft (P3) and/or the fourth feed-through voltage change ΔVft(P4). The first transmittance is less than the second transmittance and/or the third transmittance and/or the fourth transmittance. By means of this design, the original first sub-pixel P1 having a relatively severe phenomenon of image flicker is designed to be a sub-pixel that has relatively low transmittance, and the phenomenon of image flicker of the first sub-pixel P1 may be mitigated. Therefore, human eyes perceive the phenomenon of image flicker of the first sub-pixel P1 relatively slightly. Optionally, by means of a similar concept, the original second sub-pixel P2 that has a less severe phenomenon of image flicker is designed to be a sub-pixel that has lower transmittance, and the original fourth sub-pixel P4 that has the least severe phenomenon of image flicker is designed to be a sub-pixel that has the highest transmittance. The first sub-pixel P1 is, for example, a blue sub-pixel, the second sub-pixel P2 is, for example, a red sub-pixel, the third sub-pixel P3 is, for example, a green sub-pixel, and the fourth sub-pixel P4 is, for example, a white sub-pixel. Therefore, when being viewed by human eyes, for a display panel including this array substrate, a degree of image flicker is reduced. In this embodiment, a pixel that has a relatively large feed-through voltage change is set to be a pixel that has relatively low transmittance, thereby reducing differences in an image flicker problem among display panels because of mass production and/or thereby improving overall optical stability of a display panel.

In conclusion, in at least one embodiment of the present invention, an original pixel/sub-pixel that has relatively undesirable display quality (for example, a problem of image flicker is relatively severe) is designed to have relatively low transmittance, thereby improving display quality of the pixel/sub-pixel.

Although the present invention is disclosed as above by using the implementation manners, the implementation manners are not used to limit the present invention. Any person skilled in the art may make various variations and modifications without departing from the spirit and scope of the present invention, and therefore the protection scope of the present invention should be as defined by the appended claims.

What is claimed is:

1. An array substrate, comprising:
a first sub-pixel, having a first feed-through voltage change and first transmittance, wherein the first sub-pixel includes a first active element and a first pixel electrode electrically connected to the first active element;
a second sub-pixel, having a second feed-through voltage change and second transmittance, wherein the second sub-pixel includes a second active element and a second pixel electrode electrically connected to the second active element;
a third sub-pixel, having a third feed-through voltage change and third transmittance, wherein the third sub-pixel includes a third active element and a third pixel electrode electrically connected to the third active element, and the first feed-through voltage change is greater than the second feed-through voltage change or the third feed-through voltage change, and the first transmittance is less than the second transmittance or the third transmittance;
a first scan line, electrically connected to the first sub-pixel;
a second scan line, electrically connected to the second sub-pixel;
a third scan line, electrically connected to the third sub-pixel; and
a first data line, electrically connected to the third sub-pixel, wherein the second active element is electrically connected between the third pixel electrode and the second pixel electrode, and the first active element is electrically connected between the second pixel electrode and the first pixel electrode.

2. The array substrate according to claim 1, wherein the first sub-pixel is a blue sub-pixel.

3. The array substrate according to claim 2, wherein the second feed-through voltage change is greater than the third feed-through voltage change, the second transmittance is less than the third transmittance, the second sub-pixel is a red sub-pixel, and the third sub-pixel is a green sub-pixel.

4. The array substrate according to claim 3, further comprising a fourth sub-pixel, having a fourth feed-through voltage change and fourth transmittance, wherein the first feed-through voltage change is greater than the fourth feed-through voltage change, and the first transmittance is less than the fourth transmittance.

5. The array substrate according to claim 4, wherein the fourth sub-pixel comprises a fourth active element and a fourth pixel electrode electrically connected to the fourth active element, and the array substrate further comprises:
a fourth scan line, electrically connected to the fourth sub-pixel; and
wherein the first data line is electrically connected to the fourth sub-pixel, the third active element is electrically connected between the fourth pixel electrode and the third pixel electrode.

6. The array substrate according to claim 5, wherein the first sub-pixel, the second sub-pixel, the third sub-pixel, and the fourth sub-pixel are substantially sequentially disposed in an arrangement direction, and the arrangement direction is neither parallel nor perpendicular to the first scan line.

7. The array substrate according to claim 6, wherein the arrangement direction is neither parallel nor perpendicular to the first data line.

8. The array substrate according to claim 1, wherein the first sub-pixel, the second sub-pixel, and the third sub-pixel are substantially sequentially disposed in an arrangement direction, and the arrangement direction is neither parallel nor perpendicular to an extending direction of the first scan line.

9. The array substrate according to claim 8, wherein the arrangement direction is neither parallel nor perpendicular to the first data line.

10. The array substrate according to claim 1, wherein the array substrate has a display area and a peripheral area, the first scan line has a first section and a second section that are located inside the display area, and the second section is electrically connected between the first section and a gate driving circuit.

11. The array substrate according to claim 1, wherein the first sub-pixel, the second sub-pixel, and the third sub-pixel are located inside a first area, the array substrate further comprises three basic sub-pixels located inside a second area, a first distance between the first area and a edge of the array substrate is greater than a distance between the second area and the edge of the array substrate, the first sub-pixel, the second sub-pixel, and the third sub-pixel are sequentially disposed in an arrangement direction, the basic sub-pixels are also sequentially disposed in the arrangement direction, and the first sub-pixel, the second sub-pixel, and the third sub-pixel have a different color arrangement from the basic sub-pixels.

12. The array substrate according to claim 11, wherein a driving circuit is adjacent to the edge of the array substrate and is electrically connected to the first sub-pixel, the second sub-pixel, the third sub-pixel, and the basic sub-pixels, and a third distance between the first area and the driving circuit is greater than a fourth distance between the second area and the driving circuit.

13. An array substrate, comprising:
a first sub-pixel, a second sub-pixel, and a third sub-pixel that are located inside a first area; and
three basic sub-pixels, located inside a second area, wherein the first sub-pixel, the second sub-pixel, and the third sub-pixel are substantially sequentially disposed in an arrangement direction, the basic sub-pixels are substantially also sequentially disposed in the arrangement direction, a first distance between the first area and a edge of the array substrate is greater than a second distance between the second area and the edge of the array substrate, the first sub-pixel, the second sub-pixel, and the third sub-pixel have a different color arrangement from the basic sub-pixels, and the first sub-pixel is a blue sub-pixel, the second sub-pixel is a red sub-pixel, and the third sub-pixel is a green sub-pixel.

14. The array substrate according to claim 13, wherein a driving circuit is adjacent to the edge of the array substrate and is electrically connected to the first sub-pixel, the second sub-pixel, the third sub-pixel, and the basic sub-pixels, and a third distance between the first area and the driving circuit is greater than a fourth distance between the second area and the driving circuit.

15. An array substrate, comprising:
a first sub-pixel, having first transmittance, wherein the first sub-pixel includes a first active element and a first pixel electrode electrically connected to the first active element;
a second sub-pixel, having second transmittance, wherein the second sub-pixel includes a second active element and a second pixel electrode electrically connected to the second active element;
a third sub-pixel, having third transmittance, wherein the third sub-pixel includes a third active element and a third pixel electrode electrically connected to the third active element;
a first scan line, electrically connected to the first sub-pixel;
a second scan line, electrically connected to the second sub-pixel;
a third scan line, electrically connected to the third sub-pixel; and
a first data line, electrically connected to the third sub-pixel, wherein the second active element is electrically connected between the third pixel electrode and the second pixel electrode, the first active element is electrically connected between the second pixel electrode and the first pixel electrode, and the first transmittance is less than the second transmittance or the third transmittance.

16. The array substrate according to claim 15, wherein the first sub-pixel is a blue sub-pixel.

17. The array substrate according to claim 16, wherein the second sub-pixel is a red sub-pixel, and the third sub-pixel is a green sub-pixel.

18. The array substrate according to claim 15, wherein the first sub-pixel, the second sub-pixel, and the third sub-pixel are substantially sequentially disposed in an arrangement direction, the arrangement direction is neither parallel nor perpendicular to the first scan line, and the arrangement direction is neither parallel nor perpendicular to the first data line.

19. The array substrate according to claim 15, further comprising a fourth sub-pixel having fourth transmittance, wherein the fourth sub-pixel comprises a fourth active element and a fourth pixel electrode electrically connected to the fourth active element; and
a first data line, electrically connected to the fourth sub-pixel, wherein the third active element is electrically connected between the fourth pixel electrode and the third pixel electrode, and the first transmittance is less than the second transmittance or the third transmittance or the fourth transmittance.

20. The array substrate according to claim 19, wherein the first sub-pixel, the second sub-pixel, the third sub-pixel, and the fourth sub-pixel are substantially sequentially disposed in an arrangement direction, the arrangement direction is neither parallel nor perpendicular to the first scan line, the arrangement direction is neither parallel nor perpendicular to the first data line, and the second transmittance, the third transmittance, and the fourth transmittance are all less than the first transmittance.
